(19) United States
(12) Patent Application Publication
(10) Pub. No.: US 2018/0313984 A1
(43) Pub. Date: Nov. 1, 2018

(54) FRESNEL LENS AND METHOD FOR MANUFACTURING THE SAME

(71) Applicant: SHAUN YIN TECHNOLOGY CO., LTD., TAOYUAN CITY (TW)

(72) Inventors: En-Chieh Chen, Taichung City (TW); Chun-Yang Huang, Taichung City (TW)

(21) Appl. No.: 15/869,278

(22) Filed: Jan. 12, 2018

(30) Foreign Application Priority Data
Apr. 26, 2017 (TW) 106113927

(51) Int. Cl. G02B 3/08; H01L 31/0232; G02B 19/00; H01L 31/054; G02B 3/00; C03B 19/02

(52) U.S. Cl. CPC G02B 3/08; H01L 31/0232; G02B 19/0061; G02B 19/0014; H01L 31/0543; G02B 3/0068; C03B 19/025; G02B 19/0028

(57) ABSTRACT

Provided is a Fresnel lens including a lens body, a planar surface on one side of the lens body, and a Fresnel surface located on another side of the lens body opposite to the planar surface, wherein the Fresnel surface includes alternating effective portions and non-effective portions, and the non-effective portions have non-smooth microstructures.

### BACKGROUND

### 1. Technical Field

The present disclosure relates to an optical lens technology, and, more particularly, to a

Fresnel lens for reducing stray light and a method for manufacturing the same.

### 2. Description of Related Art

With the progress in science and technology, image processing has become more and more diversified. Examples include the so-called augmented reality that allows users to perform operations in a real-world environment in combination with other functions, or virtual reality (VR), in which virtual images are presented that offer users a realistic and immersive experience, and are applicable to video games, entertainment, and the like. These are major areas for current research and development.

In the case of virtual reality technology, virtual images are often provided through a head-mounted display. When a user wears the head-mounted display, an image light source comes from an image area in the head-mounted display, and there are a number of optical elements between the user's eyes and the image area. Light from the image area thus travels through the optical elements before entering into the imaging area of the human eyes, creating an image. In order to widen the field of view, an eyepiece of the head-mounted display may use a Fresnel lens, which is lightweight and low cost as well as a short manufacturing time. Refer to FIGS. 1A-1C. FIG. 1A shows a normal lens including at least a curved surface, which refracts light in order to achieve focusing or diffusion. The Fresnel lens is formed by eliminating some portions of the lens, such as dotted areas 11 in FIG. 1B. More specifically, curved portions 12 are kept for refraction, and the dotted areas 11 in the lens are removed. As a result, the remaining curved portions 12 form a Fresnel lens 1. As shown in FIG. 1C, a resulting Fresnel lens 1′ includes a planar (or non-spherical) surface 13, and the other surface is called a Fresnel surface 14. As such, the overall volume of the Fresnel lens 1′ is reduced.

As shown in FIG. 2A, a Fresnel lens 24 includes effective portions 241 and non-effective portions 242. As the curved surfaces of the effective portions 241 emulates the curved surface of a normal lens, when light passes through the effective portions 241, the refractive result is more or less the same as that achieved by the normal lens shown in FIG. 1A, such as that achieved by refractive rays 25, which indicate the desired direction of light (towards the imaging areas of the human eyes). However, if light passes through the non-effective portions 242, stray light 26 is created upon refraction, meaning the rays of this light fall onto non-desired locations after being refracted, lowering the quality of the formed images. When viewed, a resulting image may appear to be covered by a layer of fog. The reason is that the non-effective portions 242 are smooth surfaces, as shown in FIG. 2B, light rays incident on a non-effective portion 242 are refracted in the same direction towards a non-desired location (outside the imaging areas of human eyes). Thus, the existence of the non-effective portions 242 results in the generation of the stray light, which makes it difficult to improve the quality of the formed images if such issue is not addressed.

Therefore, there is a need in this art for a simple technique that reduces the stray light in the Fresnel lens without imposing high cost and complicated manufacturing processes.

### SUMMARY

In view of the aforementioned shortcomings of the prior art, the present disclosure provides a Fresnel lens applicable to a head-mounted display for reducing stray light in the Fresnel lens through modification of the structures of the non-effective portions (i.e. the non-effective surfaces).

The present disclosure provides a Fresnel lens, which may include: a lens body, a planar surface, and a Fresnel surface, wherein the planar surface is provided on one side of the lens body, the Fresnel surface is provided on another side of the lens body opposite the planar surface and includes alternating effective portions and non-effective portions, and the non-effective portions include non-smooth microstructures.

In an embodiment, the microstructures of the Fresnel lens according to the present disclosure have step-like or wave-like shapes.

In another embodiment, the microstructures are irregular structures.

In another embodiment, a draft angle of the Fresnel lens is between 0 to 10 degrees.

In yet another embodiment, the Fresnel lens described above is applicable to a head-mounted display.

The present disclosure further provides a method for manufacturing a Fresnel lens, which may include: performing surface treatment on a corresponding surface for forming a Fresnel surface of the Fresnel lens in a mold for manufacturing the Fresnel lens to form alternating smooth and non-smooth structures on the corresponding surface; and forming effective portions and non-effective portions of the Fresnel lens from a plastic material based on the alternating smooth and non-smooth structures on the corresponding surface, respectively, wherein the non-effective portions include non-smooth microstructures.

Compared to the prior art, the Fresnel lens in accordance with the present disclosure includes regular or irregular microstructures, such as wave-like or step-like microstructures, formed on its non-effective portions, so that light rays passing through the non-effective portions are refracted in many different angles, and the refracted light is not concentrated in certain directions or towards certain areas, thereby alleviating the issue of the stray light. Moreover, the manufacturing process of the Fresnel lens is simple and of high precision, and is completed in one run without the need of multiple processing sequences to be performed on the non-effective portions. Thus, the manufacturing cost is lowered, while providing a Fresnel lens with a reduced influence attributed to the stray light. The Fresnel lens can also be applied to head-mounted displays for providing a better imaging effect.

### BRIEF DESCRIPTION OF THE DRAWINGS

FIGS. 1A to 1C are schematic diagrams illustrating the composition of a traditional Fresnel lens;

FIGS. 2A and 2B are schematic diagrams illustrating refraction of light rays in non-effective portions of the traditional Fresnel lens;

FIGS. 3A and 3B are schematic diagrams illustrating a Fresnel lens and refraction of light rays thereof in accordance with the present disclosure;

FIGS. 4A to 4D are schematic diagrams illustrating refraction of light rays through non-effective portions of the Fresnel lenses in various embodiments of the present disclosure; and

FIG. 5 is a flowchart illustrating a method for manufacturing a Fresnel lens in accordance with the present disclosure.

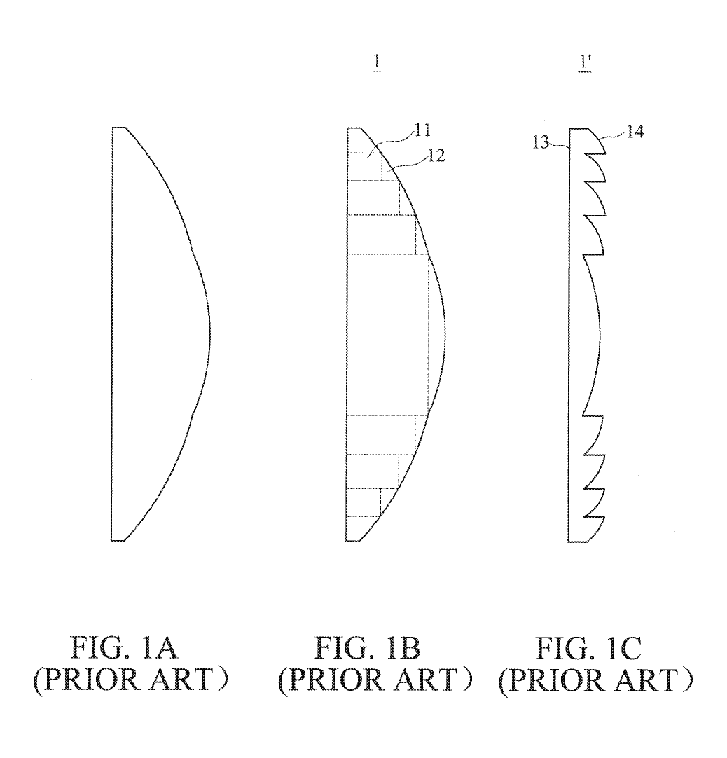

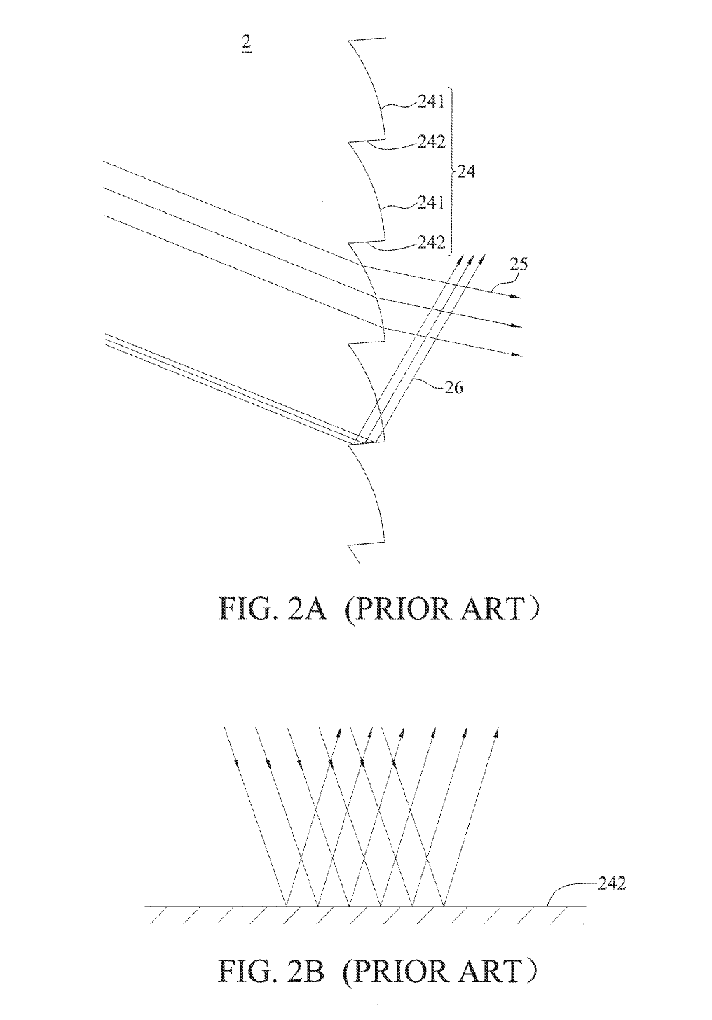

### DETAILED DESCRIPTION OF THE EMBODIMENTS

The present disclosure is described by the following specific embodiments. Those with ordinary skills in the arts can readily understand other advantages and functions of the present disclosure after reading the disclosure of this specification. The present disclosure may also be practiced or applied with other different implementations. Based on different contexts and applications, the various details in this specification can be modified and changed without departing from the spirit of the present disclosure.

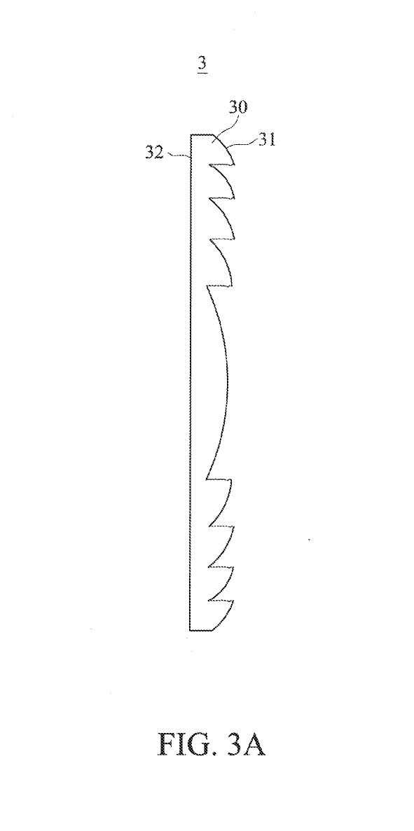

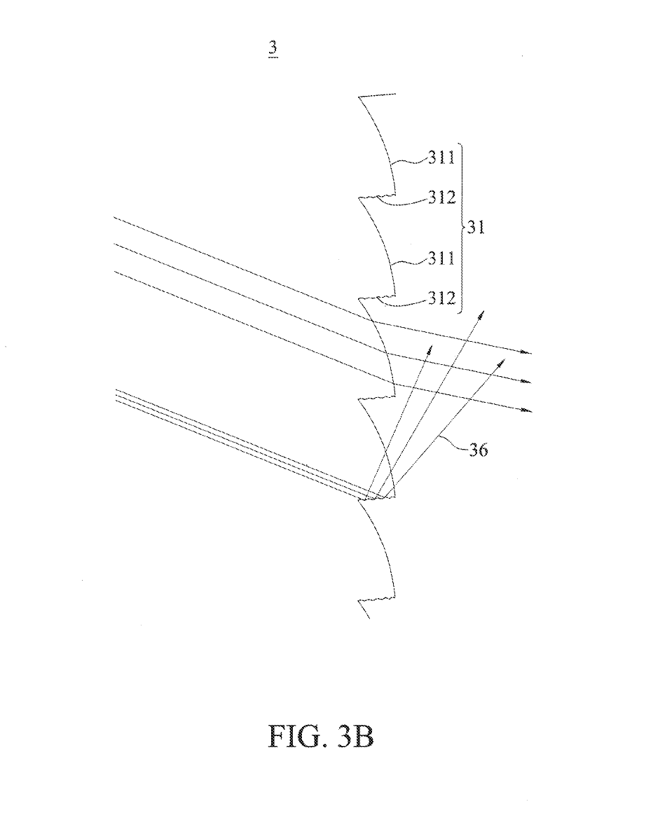

Referring to FIGS. 3A and 3B, schematic diagrams illustrating a Fresnel lens and refraction of light rays thereof in accordance with the present disclosure are shown. More specifically, in order to achieve the objective of reducing stray light, surfaces of the non-effective portions of the Fresnel lens are modified, such that light is refracted in different direction, thus reducing the influence of the stray light.

As shown in FIG. 3A, the Fresnel lens 3 according to the present disclosure includes a lens body 30, a Fresnel surface 31 and a planar surface 32. The planar surface 32 is disposed at one side of the lens body 30, and the Fresnel surface 31 is provided at the other side of the lens body 30 opposite to the planar surface 32.

As shown in FIG. 3B, a partially enlarged diagram of the Fresnel lens 3 of FIG. 3A is shown, wherein the Fresnel surface 31 includes alternating effective portions 311 and non-effective portions 312, and the non-effective portions 312 has non-smooth microstructures. As described before, when light passes through the effective portions, as the curved surfaces of the effective portions 311 emulates the curved surfaces of a normal lens, the refractive result is similar to that achieved by the normal lens, that is, light is refracted in the desired direction (towards the imaging area of human eyes). Moreover, if light passes through the non-effective portions 312, stray light 36 is formed after refraction. However, since the non-effective portions 312 are non-smooth microstructures, light rays will not be refracted in the same direction and fall on the same spot. In other words, the stray light 36 is scattered to different places without being concentrated at particular areas. This improves the imaging effect and in turn the quality of the formed images viewed by users.

In order for the stray light 36 to travel at different directions, the surfaces of the non-effective portions 312 are designed to include microstructures, such as steps or waves. The microstructures can be or not be arranged regularly. For example, when the microstructures are formed as steps or waves, the surfaces of the non-effective portions 312 are provided with regularly arranged steps or waves, or irregularly arranged steps or waves.

In an embodiment, when the Fresnel lens 3 is manufactured with molds, the draft angle can be between 0-10 degrees, which is an extraction angle given to allow a plastic finished product to be more easily extracted from the mold. By providing a draft angle, friction is reduced when the plastic finished product is taken out of the mold.

In another embodiment, the Fresnel lens according to the present disclosure is applicable to, but is not limited to, a head-mounted display. For example, it can be used in any optical equipment that requires a Fresnel lens. More specifically, the Fresnel lens of the present disclosure helps to reduce stray light.

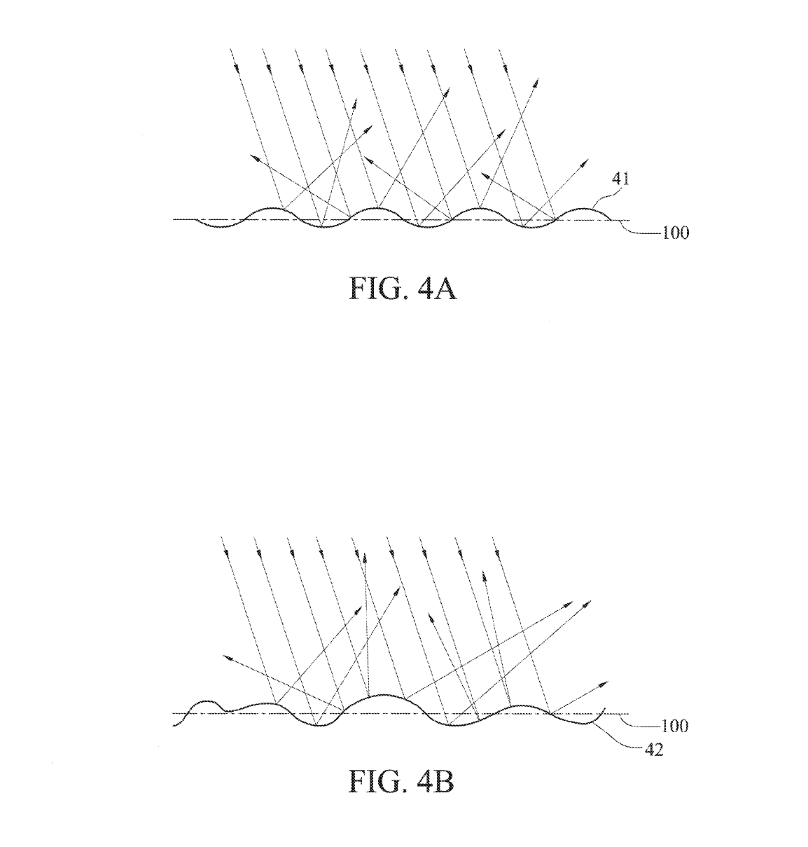

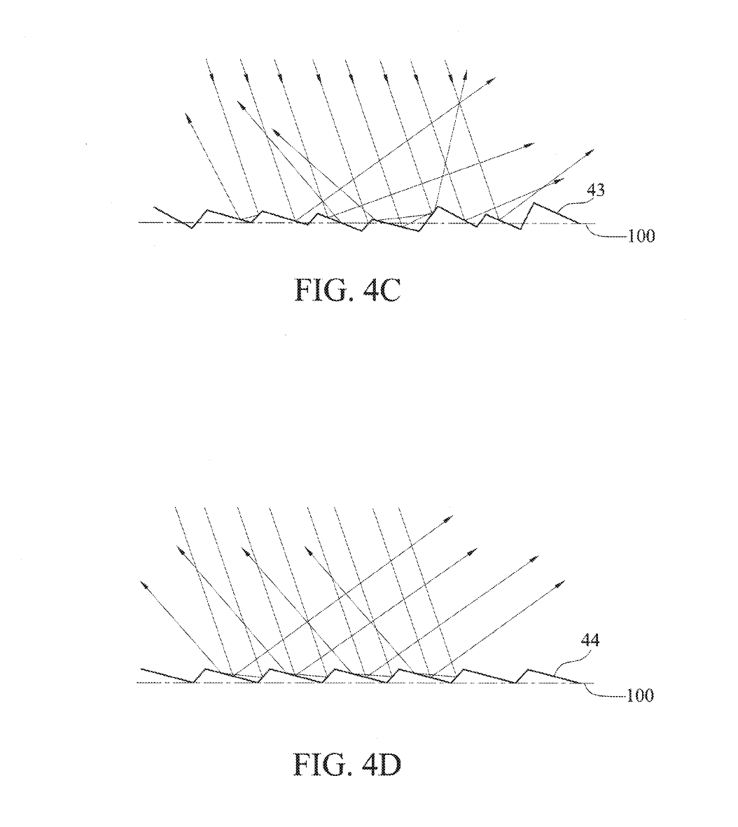

FIGS. 4A to 4D are schematic diagrams illustrating refraction of light rays through the non-effective portions of Fresnel lenses in various embodiments of the present disclosure.

As shown in FIG. 4A, non-effective portions 41 of the Fresnel surface of a Fresnel lens are formed in regular wave-like shapes with respect to a lens reference line 100. As can be seen, when light passes through the non-effective portions 41 including the microstructures, light rays are refracted in different directions due to these microstructures. Although the microstructures have a regular pattern, refracted rays travel along some directions in a regular pattern, preventing light rays (stray light) all traveling in the same direction after passing through the non-effective portions.

As shown in FIG. 4B, non-effective portions 42 of the Fresnel surface of a Fresnel lens are formed in irregular wave-like shapes with respect to a lens reference line 100. As can be seen, when light passes through the non-effective portions 42 including the microstructures, light rays are refracted in different directions due to these microstructures. Since the microstructures have an irregular pattern, refracted rays travel along some directions in an irregular manner, facilitate scattering of light after being refracted and preventing the shortcoming in which all light rays travel in the same direction.

As shown in FIG. 4C, non-effective portions 43 of the Fresnel surface of a Fresnel lens are formed in irregular step-like shapes with respect to a lens reference line 100. As can be seen, when light passes through the non-effective portions 43 including the microstructures, light rays are refracted in different directions due to these microstructures. Since the microstructures have an irregular pattern, refracted rays travel along some directions in an irregular manner, preventing stray light of a conventional Fresnel lens being concentrated at certain areas.

As shown in FIG. 4D, non-effective portions 44 of the Fresnel surface of a Fresnel lens are formed in regular step-like shapes with respect to a lens reference line 100. As can be seen, when light passes through the non-effective portions 44 including the microstructures, light rays are refracted in different directions due to these microstructures. Although the microstructures have a regular pattern, refracted rays travel along some directions in a regular pattern, it still achieves an imaging effect better than the case where all light rays (stray light) travel in the same direction after passing through the non-effective portions, thereby providing better image quality.

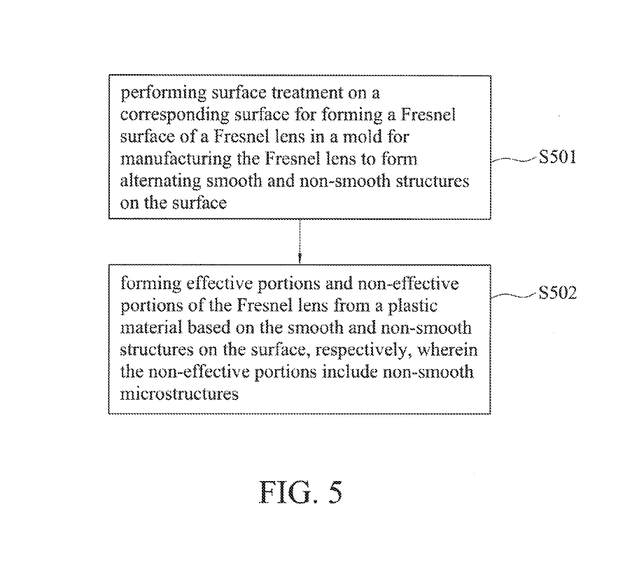

Referring to FIG. 5, a flowchart illustrating a method for manufacturing a Fresnel lens in accordance with the present disclosure is shown. In step S501, surface treatment is performed on a corresponding surface of a mold for forming to the Fresnel surface of the Fresnel lens to form alternating non-smooth and smooth structures.

Simply put, the Fresnel lens can be manufactured by injection molding. Thus, this step provides a mold, wherein a surface for forming the Fresnel surface of the Fresnel lens in the mold is surface treated first, such that alternating smooth and non-smooth structures are formed on the surface of the mold.

The smooth structures described above are portions on the Fresnel surface that are equivalent to the curved surface of a normal lens. These smooth structures allows light to be refracted in the same way as a normal lens would since they have the same curvatures of a normal lens.

Moreover, the non-smooth structures described above are microstructures in regular or irregular step- or wave-like shapes.

In step S502, effective portions and non-effective portions of a Fresnel lens are formed from a plastic material based on the smooth and non-smooth structures on the surface of the mold, respectively, wherein the non-effective portions include non-smooth microstructures.

In step S502, a plastic material is formed on the mold, such that portions of the plastic material corresponding to the smooth and non-smooth structures on the surface of the mold form effective portions and non-effective portions of the Fresnel lens, respectively. In other words, the effective portions of the Fresnel surface has the same refraction result as a normal lens, while the non-effective portions of the Fresnel surface generates stray light. According to the present disclosure, the non-effective portions are designed with microstructures to scatter the stray light.

In an embodiment, the draft angle of the Fresnel lens is designed to be between 0-10 degrees to facilitate the extraction of the Fresnel lens from the mold.

In conclusion, the Fresnel lens in accordance with the present disclosure includes regular or irregular microstructures formed on its non-effective portions, so that light rays passing through the non-effective portions are refracted in many different angles, and the refracted light, i.e., the stray light, is not concentrated in certain directions or towards certain areas, alleviating the issue of poor image quality caused by the stray light. Moreover, during the manufacturing of the Fresnel lens, only the areas of the mold to be formed as the non-effective portions are provided with the microstructures, which allows the non-effective portions of the plastic material later formed to have the microstructures. This manufacturing process not only has high precision, but requires just one run without the need of multiple processing sequences to be performed on the non-effective portions, thereby lowering the manufacturing cost, while providing a good quality Fresnel lens.

The above embodiments are only used to illustrate the principles of the present disclosure, and should not be construed as to limit the present disclosure in any way. The above embodiments can be modified by those with ordinary skill in the art without departing from the scope of the present disclosure as defined in the following appended claims.

What is claimed is:

1. A Fresnel lens, comprising:
a lens body;
a planar surface provided on one side of the lens body; and
a Fresnel surface provided on another side of the lens body opposite the planar surface and including alternating effective portions and non-effective portions, wherein the non-effective portions include non-smooth microstructures.

2. The Fresnel lens of claim 1, wherein the microstructures have step-like or wave-like shapes.

3. The Fresnel lens of claim 1, wherein the microstructures are irregular microstructures.

4. The Fresnel lens of claim 1, having a draft angle ranging between 0 to 10 degrees.

5. A head-mounted display comprising the Fresnel lens of claim 1.

6. A method for manufacturing a Fresnel lens, comprising:
performing surface treatment on a corresponding surface for forming a Fresnel surface of the Fresnel lens in a mold for manufacturing the Fresnel lens to form alternating smooth and non-smooth structures on the corresponding surface; and
forming effective portions and non-effective portions of the Fresnel lens from a plastic material based on the alternating smooth and non-smooth structures on the corresponding surface, respectively, wherein the non-effective portions include non-smooth microstructures.

7. The method of claim 6, wherein the microstructures have step-like or wave-like shapes.

8. The method of claim 6, wherein the microstructures are irregular microstructures.

9. The method of claim 6, wherein the Fresnel lens has a draft angle ranging between 0 to 10 degrees.
